(19) United States
(12) Patent Application Publication
(10) Pub. No.: US 2008/0264675 A1
(43) Pub. Date: Oct. 30, 2008

(54) PRINTED CIRCUIT BOARD AND METHOD FOR MANUFACTURING THE SAME

(75) Inventors: WEN-CHIN LEE, Tayuan (TW); CHENG-HSIEN LIN, Tayuan (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN ADVANCED TECHNOLOGY INC., Tayuan (TW)

(21) Appl. No.: 11/847,297

(22) Filed: Aug. 29, 2007

(30) Foreign Application Priority Data
Apr. 25, 2007 (CN) 200710074220.9

(51) Int. Cl. H05K 1/00; B23K 26/38

(52) U.S. Cl. 174/250; 219/121.69

(57) ABSTRACT

An exemplary method for manufacturing a printed circuit board is provided. In the method, firstly, a circuit substrate having a substrate and a number of soldering pads is provided. Secondly, a protective layer is formed onto the circuit substrate in a manner such that the soldering pads are entirely covered by the protective layer. Fourthly, a laser beam is applied onto portions of the protective layer spatially corresponding to the soldering pads in a manner such that the portions of the protective layer is removed, thereby exposing the soldering pads to an exterior. A printed circuit board having a protective layer with high precision of resolution is also provided.

### BACKGROUND

1. Technical Field

The present invention relates to printed circuit boards and methods for manufacturing printed circuit boards.

2. Description of Related Art

Protective material such as solder resist (i.e., solder mask) is often applied on a printed circuit board to protect all surface features of the printed circuit board except some specific areas such as soldering pads. Solder resist is a resin formulation, generally green in color. Solder resist can form a permanent protective coating on the printed circuit board in order to prevent from wetting and mechanical damage, and provide electrical insulation and protection against oxidation and corrosion.

Generally, a liquid photoimageable (LPI) solder resist is used to form a solder resist layer (a protective layer) on the printed circuit board. A process of forming the solder resist layer generally includes steps of applying, pre-curing, exposing, developing, post curing and printing. The solder resist layer can cover the printed circuit board and leave the soldering pads on the printed circuit board free for soldering tin. During exposing and developing of the LPI solder resist, a mask having openings corresponding to the soldering pads on the printed circuit board is needed. The LPI solder resist can be photographically imaged and developed in corresponding portions using the mask and leave the soldering pads on the printed circuit board free from the LPI solder resist.

However, not only can the openings of the mask and the soldering pads on the printed circuit board undergo positional excursion thereby affecting precision of the solder resist layer, but also some solder resist can be left on the soldering pads thereby affecting electrical connection. Moreover, nowadays electronic products have achieved ever greater levels of miniaturization. In order to accommodate these electronic products, fine-pitch soldering pad designs of the printed circuit board have become more and more popular. Therefore, the method described above cannot achieve the necessary precision of resolution demanded by fine-pitch soldering pad designs of the printed circuit board.

What is needed, therefore, is a printed circuit board having a protective layer with a high precision of resolution and a method for manufacturing the printed circuit board.

### SUMMARY

One preferred embodiment includes a printed circuit board. The printed circuit board includes a circuit substrate having a substrate and a number of soldering pads formed thereon. A protective layer is formed on the circuit substrate. The protecting layer has a number of soldering pad windows defined using laser treatment. The soldering pads each has a portion exposed to an exterior through the respective soldering pad windows.

Another preferred embodiment provides a method for manufacturing a printed circuit board. In the method, firstly, a circuit substrate having a substrate and a number of soldering pads is provided. Secondly, a protective layer is formed onto the circuit substrate in a manner such that the soldering pads are entirely covered by the protective layer. Thirdly, a laser beam is applied onto portions of the protective layer spatially corresponding to the soldering pads in a manner such that the portions of the protective layer are removed, thereby exposing the soldering pads to an exterior.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1A is a schematic, cross-sectional views of a circuit substrate according to a preferred embodiment.

FIG. 1B is a schematic, cross-sectional views of the circuit substrate having a solder resist material applied thereon.

FIG. 1C is a schematic, cross-sectional views of the circuit substrate having a solder resist layer formed thereon.

FIG. 1D is a schematic, cross-sectional views of a printed circuit board using a method according to a preferred embodiment.

### DETAILED DESCRIPTION OF THE EMBODIMENTS

Embodiments will now be described in detail below and with reference to the drawings.

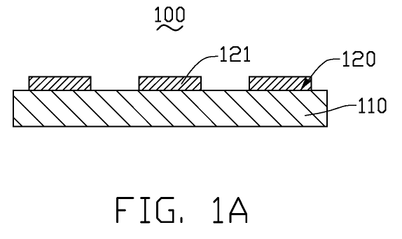

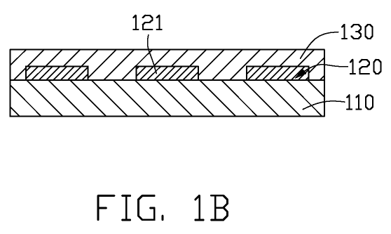

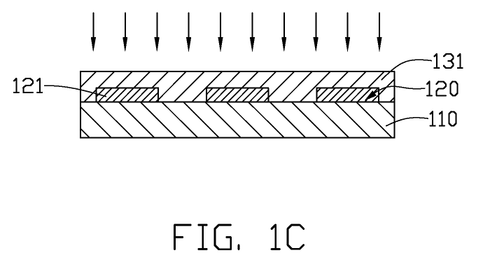

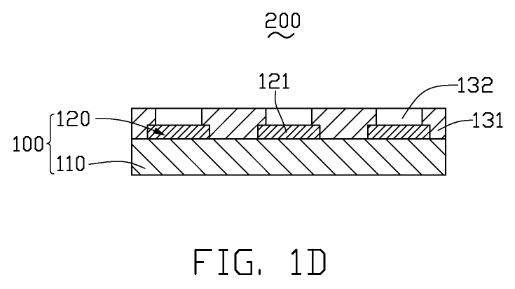

Referring to FIGS. 1A˜1D, an exemplary method for manufacturing a printed circuit board 200 includes the following steps.

Step 1: a circuit substrate 100 having a substrate 110 and a number of soldering pads 121 is provided.

The circuit substrate 100 can be a rigid printed circuit substrate or a flexible printed circuit substrate. The circuit substrate 100 can be a single-layer structure or a multilayer structure containing two layers, four layers, six layers or more. In the preferred embodiment, referring to FIG. 1A, the circuit substrate 100 is a single-layer single-side structure. The circuit substrate 100 includes the substrate 110 and the number of soldering pads 121 formed on one side of the substrate 110. The soldering pads 121 a part of a patterned conductive layer 120 formed on the circuit substrate 100. The substrate 110 is a flexible substrate such as polyimide film. The patterned conductive layer 120 is formed with a copper foil on the substrate 110. A number of conductive traces (not shown) and soldering pads 121 can be formed with the copper foil. The soldering pads 121 are configured for electrically connecting with the outside electronic component. The conductive traces and the soldering pads 121 can be formed using a photolithographic process or other usable processes. Additionally, the circuit substrate 100 can have the patterned conductive layer 120 formed on two opposite sides of the substrate 110 to form a single-layer two-sided structure. Thus the soldering pads 121 can be formed on two opposite sides of the substrate 110.

Step 2: a solder resist layer 131 is formed onto the circuit substrate 100 in a manner such that the soldering pads 121 are entirely covered by the a solder resist layer 131. The solder resist layer 131 is a protective layer to protect all surface features of the circuit substrate 100 except some specific areas such as soldering pads 121.

Firstly, a solder resist material 130 is applied onto the circuit substrate 100 in a manner such that the soldering pads 121 is entirely covered by the solder resist material 130.

Referring to FIG. 1B, the solder resist material 130 is applied on the circuit substrate 100. That is the solder resist material 130 is applied on the soldering pads 121 and the substrate 110 exposed from conductive traces and the soldering pads 121 of the patterned conductive layer 120 so that the soldering pads 121 is entirely covered by the solder resist material 130. The solder resist material 130 can be a thermally curable solder resist material. The thermally curable solder resist material can have a main thermally curable resin composition such as epoxy resin, amino resin and polymethyl methacrylate resin. Such thermally curable solder resist material has excellent adhesion, stability and flexibility. The solder resist material 130 can be applied on the circuit substrate 100 using a method selected from a group consisting of screen-printing, curtain coating, spray coating and rolling coating. In the preferred embodiment, the solder resist material 130 including epoxy resin as the main resin composition is applied onto the circuit substrate 100 using screen-printing. A thickness of the solder resist material 130 is about 0.5 mil (0.127 millimeters).

Secondly, the solder resist material 130 is cured so as to form a solder resist layer 131.

Referring to FIG. 1C, the circuit substrate 100 having the solder resist material 130 applied thereon is heated. Thus the solder resist material 130 is heat cured to form a solder resist layer 131. Time and a temperature spent heating can differ according to different compositions of the solder resist material 130. In the preferred embodiment, because the solder resist material 130 having epoxy resin as the main resin composition is used, the circuit substrate 100 having solder resist material 130 applied thereon can be heated to 80˜100 degrees Celsius for about 2˜4 hours in an oven. As a result, the solder resist layer 131 is formed on the circuit substrate 100.

It is noted that the protective layer can be formed by other protective layer materials. For example, a coverlay can be formed onto the circuit substrate 100 to serve as the protective layer. The coverlay can contain polyimide, or polyethylene terephalate or polyethylene naphthalate, and so on.

Step 3: a laser beam is applied onto portions of the solder resist layer 131 spatially corresponding to the soldering pads 121 in a manner such that the portions of the solder resist layer 131 is removed, thereby exposing the soldering pads 121 to an exterior.

Referring to FIG. 1D, a laser apparatus produces the laser beam to melt and remove portions of the solder resist layer 131 spatially corresponding to the soldering pads 121. Thus a number of soldering pad windows 132 corresponding to the soldering pads 121 is formed and the soldering pads 121 are exposed from the solder resist layer 131 to an exterior. A size of each of the soldering pad windows 132 can be smaller than that of corresponding soldering pad 121. The laser apparatus can automatically instruct the laser beam to go to the portions of the solder resist layer 131 spatially corresponding to the soldering pads 121 being melted. The solder resist layer 131 can thus be formed with a high degree of precision, when the soldering pads 121 have a fine-pitch soldering pad configuration.

The laser beam produced can be an ultraviolet laser beam or a dioxide carbon laser beam. The ultraviolet laser beam can be a neodymium-yttrium aluminum garnet (Nd:YAG) laser beam. The dioxide carbon laser beam produces a beam of infrared light with the principal wavelength bands centering around 9.4 and 10.6 micrometers. An energy density of the laser beam can be determined according to the thickness and the composition of the protective layer. In the preferred embodiment, the protective layer is the solder resist layer 131. Preferrably, the dioxide carbon laser beam is used to form a number of soldering pad windows 132 in the solder resist layer 131. Because the dioxide carbon laser beam can not melt and remove metals of the soldering pads 121, but only melt and remove the solder resist material of the solder resist layer 131 to form a number of soldering pad windows 132 in the solder resist layer 131.

Further, the laser beam can melt an opening with a diameter in a range from 0.025˜0.15 millimeters in the solder resist layer 131. Because the soldering pad windows 132 is formed by melting portions of the solder resist layer 131 spatially corresponding to the soldering pads 121 using the laser beam, a diameter of each of the soldering pad windows 132 can also be in a range from 0.025 to 0.15 millimeters. Therefore, a diameter of each of the soldering pads 121 formed on the circuit substrate 100 can be in a range form 0.025 to 0.15 millimeters, thereby forming a soldering pad with a fine-pitch configuration. A density of the soldering pads 121 on the circuit substrate 100 within a certain area can be increased.

Referring to FIG. 1D, the printed circuit board 200 formed using the method described above is provided. The printed circuit board 200 includes the circuit substrate 100 and the solder resist layer 131 (the protective layer). The circuit substrate 100 has the substrate 110 and a number of soldering pads 121 formed on the substrate 110. The soldering pads 121 have a fine-pitch soldering pad configuration. The diameter of each of the soldering pads 121 formed on the circuit substrate 100 can be in a range form 0.025 to 0.15 millimeters. The soldering pads 121 are configured for electrically connecting with the outside electronic component. The solder resist layer 131 is formed on the circuit substrate 100. The solder resist layer 131 has a number of soldering pad windows 132 defined by means of a laser treatment. The soldering pad windows 132 each have a portion exposed to an exterior. The diameter of each of the soldering pad windows 132 is in a range from 0.025 to 0.15 millimeters. The precision of the soldering pad windows 132 can be enhanced.

Then, appearances of the solder resist layer 131 (the protective layer) of the printed circuit board 200 and the soldering pads 121 exposed are checked for irregularities. If the appearances are normal, the successive steps such as electroless nickel/immersion gold (ENIG), immersion tin and tin spraying, can be performed. In these steps, the solder resist layer 131 (the protective layer) can prevent wetting and mechanical damage, and provide electrical insulation and protection against oxidation and corrosion.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A method for manufacturing a printed circuit board, comprising the steps of:
providing a circuit substrate having a substrate and a plurality of soldering pads formed thereon;
forming a protective layer onto the circuit substrate in a manner such that the soldering pads are entirely covered by the protective layer; and
applying a laser beam onto portions of the protective layer spatially corresponding to the plurality of soldering pads in a manner such that the portions of the protective layer is removed, thereby exposing the plurality of soldering pads to an exterior.

2. The method as claimed in claim 1, wherein the protective layer is a solder resist layer, forming a protective layer comprising steps of applying a solder resist material onto the circuit substrate in a manner such that the plurality of soldering pads is entirely covered by the solder resist material; and curing the solder resist material so as to form a solder resist layer.

3. The method as claimed in claim 2, wherein the solder resist material is a thermally curable solder resist material.

4. The method as claimed in claim 3, wherein the thermally curable solder resist material is selected from a group consisting of epoxy resin solder resist, amino resin solder resist and a polymethyl methacrylate resin solder resist.

5. The method claimed in claim 2, wherein in the step of applying the solder resist material, the solder resist material is applied onto the circuit substrate using a method selected from a group consisting of screen-printing, curtain coating, spray coating and rolling coating.

6. The method claimed in claim 1, wherein the protective layer is a coverlay, the coverlay comprising a material selected from a group consisting of polyimide, or polyethylene terephalate or polyethylene naphthalate.

7. The method as claimed in claim 1, wherein the laser beam is selected from a group consisting of an ultraviolet laser beam and a dioxide carbon laser beam.

8. A printed circuit board, comprising:
a circuit substrate having a substrate and a plurality of soldering pads formed thereon; and
a protective layer formed on the circuit substrate, the protective layer having a plurality of soldering pad windows defined using laser treatment, the plurality of soldering pads each having a portion exposed to an exterior through the respective pad windows.

9. The printed circuit board claimed in claim 8, wherein a diameter of each of the soldering pad windows is in a range from 0.025 to 0.15 millimeters.

10. The printed circuit board as claimed in claim 8, wherein the protective layer is a solder resist layer.

11. The printed circuit board claimed in claim 10, wherein the solder resist layer is comprised of a thermally curable solder resist material.

12. The printed circuit board claimed as claimed in claim 11, wherein the thermally curable solder resist material is selected from a group consisting of epoxy resin solder resist, amino resin solder resist and a polymethyl methacrylate resin solder resist.

13. The method claimed in claim 8, wherein the protective layer is a coverlay, the coverlay comprising a material selected from a group consisting of polyimide, or polyethylene terephalate or polyethylene naphthalate.

14. The method as claimed in claim 8, wherein the laser beam is selected from a group consisting of an ultraviolet laser beam and a dioxide carbon laser beam.
